(19) United States
(12) Patent Application Publication
(10) Pub. No.: US 2008/0150011 A1
(43) Pub. Date: Jun. 26, 2008

(54) INTEGRATED CIRCUIT SYSTEM WITH MEMORY SYSTEM

(75) Inventors: Simon Siu-Sing Chan, Saratoga, CA (US); Lei Xue, Sunnyvale, CA (US); YouSeok Suh, Cupertino, CA (US); Amol Ramesh Joshi, Sunnyvale, CA (US); Hidehiko Shiraiwa, San Jose, CA (US); Harpreet Sachar, Milpitas, CA (US); Kuo-Tung Chang, Saratoga, CA (US); Connie Pin Chin Wang, Mountain View, CA (US); Paul R. Besser, Sunnyvale, CA (US); Shenqing Fang, Fremont, CA (US); Meng Ding, Sunnyvale, CA (US); Takashi Orimoto, Sunnyvale, CA (US); Wei Zheng, Santa Clara, CA (US); Fred TK Cheung, San Jose, CA (US)

Correspondence Address: FARJAMI & FARJAMI LLP, 26522 LA ALAMEDA AVENUE, SUITE 360, MISSION VIEJO, CA, 92691, US

(73) Assignees: SPANSION LLC, Sunnyvale, CA (US); ADVANCED MICRO DEVICES, INC., Sunnyvale, CA (US)

(21) Appl. No.: 11/958,646

(22) Filed: Dec. 18, 2007

Related U.S. Application Data
(60) Provisional application No. 60/871,432, filed on Dec. 21, 2006.

(51) Int. Cl. H01L 27/115; H01L 21/8247

(52) U.S. Cl. 257/326; 438/287; 257/E27.103; 257/E21.691

(57) ABSTRACT

A method for forming an integrated circuit system is provided including forming a substrate having a core region and a periphery region, forming a charge storage stack over the substrate in the core region, forming a gate stack with a stack header having a metal portion over the substrate in the periphery region, and forming a memory system with the stack header over the charge storage stack.

### CROSS-REFERENCES TO RELATED APPLICATION

This application claims the benefit of U.S. Provisional Patent Application No. 60/871,432 filed Dec. 21, 2006.

### TECHNICAL FIELD

The present invention relates generally to integrated circuit systems and more particularly to integrated circuit systems having a memory system.

### BACKGROUND ART

Modern electronics, such as smart phones, personal digital assistants, location based services devices, digital cameras, music players, servers, and storage arrays, are packing more integrated circuits into an ever shrinking physical space with expectations for decreasing cost. One cornerstone for electronics to continue proliferation into everyday life is the non-volatile storage of information such as cellular phone numbers, digital pictures, or music files. Numerous technologies have been developed to meet these requirements.

There are many types of non-volatile data storage, such as Hard Disk Drives, magneto-optical drives, compact disk (CD), digital versatile disk (DVD), and magnetic tape. However, semiconductor based memory technologies have advantages of very small size, mechanical robustness, and low power. These advantages have created the impetus for various types of non-volatile memories, such as electrically erasable programmable read only memory (EEPROM) and electrically programmable read only memory (EPROM). EEPROM can be easily erased without extra exterior equipment but with reduced data storage density, lower speed, and higher cost. EPROM, in contrast, is less expensive and has greater density but lacks erasability.

A newer type of memory called “Flash” EEPROM, or Flash memory, has become popular because it combines the advantages of the high density and low cost of EPROM with the electrical erasability of EEPROM. Flash memory can be rewritten and can hold its contents without power. Contemporary Flash memories are designed in a floating gate or a charge trapping architecture. Each architecture has its advantages and disadvantages.

The floating gate architecture offers implementation simplicity. This architecture embeds a gate structure, called a floating gate, inside a conventional metal oxide semiconductor (MOS) transistor gate stack. Electrons can be injected and stored in the floating gate as well as erased using an electrical field or ultraviolet light. The stored information may be interpreted as a value “0” or “1” from the threshold voltage value depending upon charge stored in the floating gate. As the demand for Flash memories increases, the Flash memories must scale with new semiconductor processes. However, new semiconductor process causes a reduction of key feature sizes in Flash memories of the floating gate architecture, which results in undesired increase in programming time, and decrease in data retention.

The charge trapping architecture offers improved scalability to new semiconductor processes compared to the floating gate architecture. One implementation of the charge trapping architecture is a silicon-oxide-nitride-oxide semiconductor (SONOS) where the charge is trapped in the nitride layer. The oxide-nitride-oxide structure has evolved to an oxide-silicon rich nitride-oxide (ORO) for charge trapping structure. Leakage and charge-trapping efficiency are two major parameters considered in device performance evaluation. Charge-trapping efficiency determines if the memory devices can keep enough charges in the storage nodes after program/erase operation and is reflected in retention characteristics. It is especially critical when the leakage behavior of storage devices is inevitable.

Memories generally operate with other devices or functions. Memory integration with other functional blocks, such as logic, processors, or analog blocks, is also common and involves trade-offs. Some of these trade-offs include number of process steps, process technology complexities, performance trade-offs between different functional blocks, reliability, cost, and overall integrated device yield. Integrated circuits with memory continue to demand higher density and larger memory space while wrestling with other integration trade-offs.

Thus, a need still remains for an integrated circuit system with memory integration providing low cost manufacturing, improved yields, improved programming performance, and improved data density of memory in a system. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including forming a substrate having a core region and a periphery region, forming a charge storage stack over the substrate in the core region, forming a gate stack with a stack header having a metal portion over the substrate in the periphery region, and forming a memory system with the stack header over the charge storage stack.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIGS. 1A, 1B, and 1C are schematic views of examples of electronics systems in which various aspects of the present invention may be implemented;

FIG. 2 is a plan view of an integrated circuit system in an embodiment of the present invention;

FIG. 3 is a more detailed plan view of a portion of the memory systems of FIG. 2;

FIG. 4 is a cross-sectional view of the integrated circuit system along a line segment 4-4 of FIG. 2 in an embodiment of the present invention;

FIG. 5 is a cross-sectional view of the integrated circuit system of FIG. 4 in an isolation forming phase;

FIG. 6 is the structure of FIG. 5 in a stack forming phase;

FIG. 7 is the structure of FIG. 6 in a filler forming phase;

FIG. 8 is the structure of FIG. 7 in a metal forming phase; and

FIG. 9 is a flow chart of an integrated circuit system for manufacture of the integrated circuit system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. In addition, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

The term “processing” as used herein includes deposition of material, patterning, exposure, development, etching, cleaning, molding, and/or removal of the material or as required in forming a described structure. The term “system” as used herein means and refers to the method and to the apparatus of the present invention in accordance with the context in which the term is used.

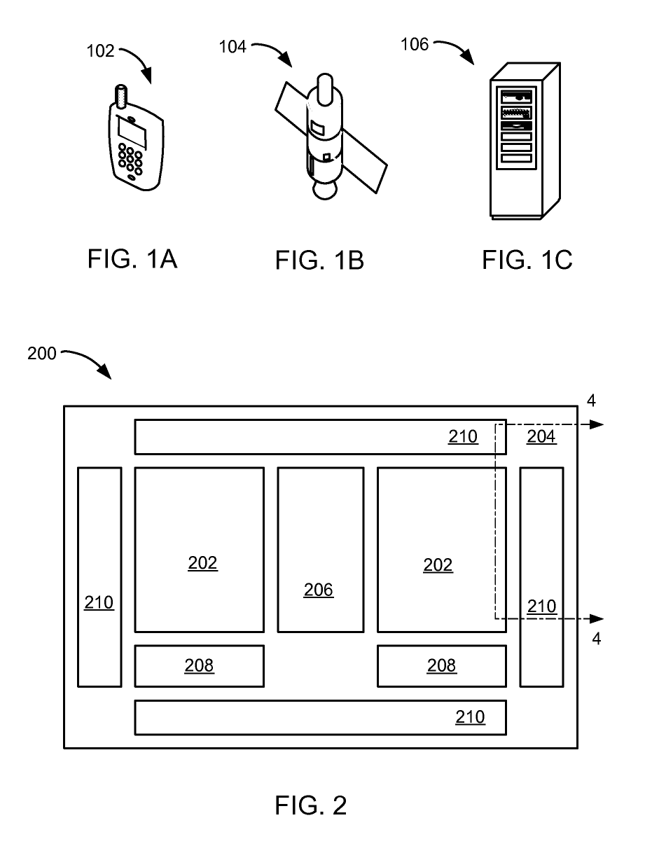

Referring now to FIGS. 1A, 1B, and 1C, therein are shown schematic views of examples of electronics systems in which various aspects of the present invention may be implemented. A smart phone 102, a satellite 104, and a compute system 106 are examples of the electronic systems using the present invention. The electronic systems may be any system that performs any function for the creation, transportation, storage, and consumption of information. For example, the smart phone 102 may create information by transmitting voice to the satellite 104. The satellite 104 is used to transport the information to the compute system 106. The compute system 106 may be used to store the information. The smart phone 102 may also consume information sent from the satellite 104.

The electronic systems, such as the smart phone 102, the satellite 104, and the compute system 106, include a one or more subsystem, such as a printed circuit board having the present invention or an electronic assembly having the present invention. The electronic system may also include a subsystem, such as an adapter card.

Referring now to FIG. 2, therein is shown a plan view of an integrated circuit system 200 in an embodiment of the present invention. The plan view depicts memory systems 202 in a substrate 204, such as a semiconductor substrate, wherein the substrate 204 has one or more high-density core regions and one or more low-density peripheral portions are formed.

High-density core regions typically include one or more of the memory systems 202. Low-density peripheral portions typically include peripheral circuitry 210, such as input/output (I/O) circuitry or transistors interfacing to the memory systems 202, and programming circuitry for individually and selectively addressing a location in each of the memory systems 202.

The programming circuitry is represented in part by and includes one or more x-decoders 206 and y-decoders 208, cooperating with the peripheral circuitry 210 for connecting the source, gate, and drain of selected addressed memory cells to predetermined voltages or impedances to effect designated operations on the memory cell, e.g. programming, reading, and erasing, and deriving necessary voltages to effect such operations. For illustrative purposes, the integrated circuit system 200 is shown as a memory device, although it is understood that the integrated circuit system 200 may include other semiconductor devices having other functional blocks, such as a digital logic block, a processor, or other types of memories.

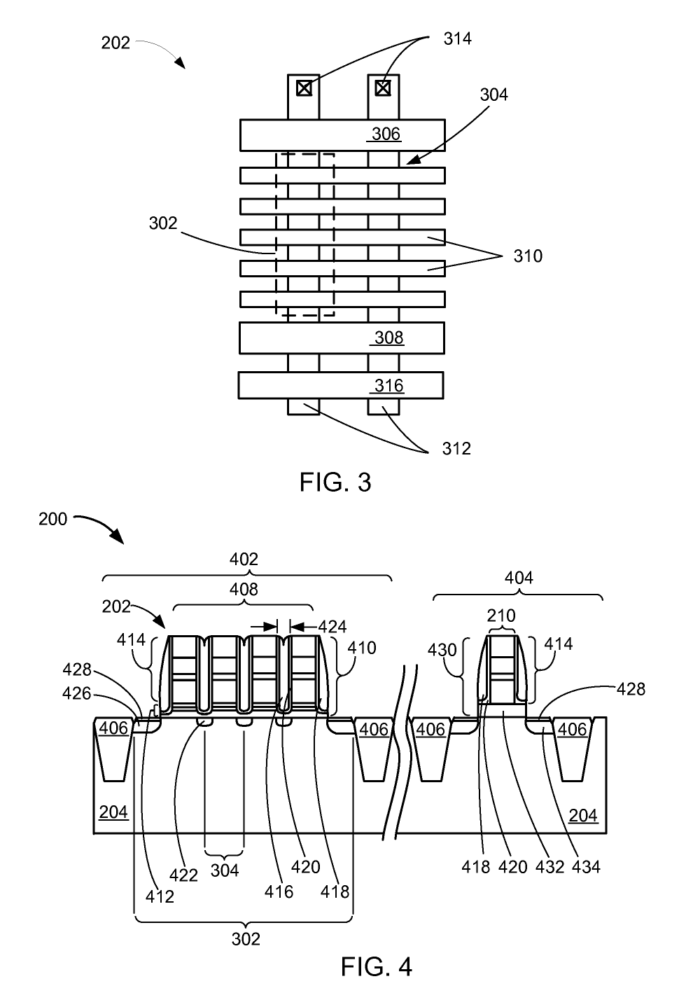

Referring now to FIG. 3, therein is shown a more detailed plan view of a portion of the memory systems 202 of FIG. 2. The plan view depicts two instances of a memory section 302, such as NAND memory series, in each column. The memory section 302 has memory cells 304 between a drain select line 306 and a source select line 308. The memory cells 304 preferably have word lines 310 above bit lines 312, wherein the word lines 310 and the bit lines 312 are perpendicular to each other. The drain select line 306 and the source select line 308 are also preferably perpendicular to the bit lines 312. Contacts 314, such as drain contacts, are preferably on the bit lines 312 next to the drain select line 306. A common source line 316 is preferably perpendicular to the bit lines 312 and next to the source select line 308.

Referring now to FIG. 4, therein is a cross-sectional view of the integrated circuit system 200 along a line segment 4-4 of FIG. 2 in an embodiment of the present invention. The cross-sectional view depicts a portion of the integrated circuit system 200 having a core region 402 and a periphery region 404. The core region 402 is a portion of the memory systems 202. The periphery region 404 includes the peripheral circuitry 210.

The core region 402 preferably has isolation structures 406, such as shallow trench isolation (STI), in the substrate 204 isolating an inner core 408 of the core region 402 between the isolation structures 406 from other portions of the core region 402 or the substrate 204. For example, the substrate 204 in the inner core 408 may be doped differently than the substrate 204 in other parts of the core region 402 or other portions of the substrate 204. The isolation structures 406 may also preferably isolate the periphery region 404 from other portions of the substrate 204. For illustrative purposes, the isolation structures 406 in the core region 402 and the periphery region 404 are shown substantially the same, although it is understood that the isolation structures 406 may not be the same between the core region 402 and the periphery region 404.

The inner core 408 preferably has the memory section 302 over the substrate 204. The memory section 302 has a plurality of memory stacks 410 over the substrate 204. Each of the memory stacks 410 preferably includes a charge storage stack 412, such as an oxide-silicon rich nitride-oxide (ORO) stack, and one of stack headers 414 over the charge storage stack 412. The charge storage stack 412 or a portion thereof may also be continuous extending between the memory stacks 410 that are adjacent to each other and over the substrate 204 if lateral charge movement is not expected. A gap filler 416, such as a nitride filler, is between adjacent instances of the memory stacks 410. A spacer 418, such as a nitride spacer, is also along a sidewall 420 of each of the memory stacks 410 at the ends of the memory section 302.

An inner doped region 422, such as an n-minus doped region, in the substrate 204 is under a gap 424 between the memory stacks 410. For example, the gap 424 may be in the range about 20 nm to 100 nm. An outer doped region 426, such as an n-plus doped region, in the substrate 204 is between the isolation structures 406 and the spacer 418. A low resistivity layer 428, such as a silicide, is located at a top portion of the outer doped region 426. The low resistivity layer 428 may serve multiple functions but is optional. For example, the low resistivity layer 428 enhances performance of the memory systems 202. One of the memory cells 304 includes one of the memory stacks 410 and the adjacent instances of the inner doped region 422. The inner doped region 422 may function as a source or drain in the memory section 302. The outer doped region 426 may function as a source or drain of the memory section 302.

The cross-sectional view also shows an instance of the peripheral circuitry 210 in the periphery region 404. The peripheral circuitry 210 has a gate stack 430 over the substrate 204. The gate stack 430 has a dielectric liner 432, such as thin oxide or gate oxide liner, over the substrate 204 and an instance of the stack headers 414 over the dielectric liner 432. The spacer 418 is also along the sidewall 420 of one instance of the stack headers 414 of the periphery region 404. A periphery doped region 434, such as an n-plus doped region, is between the isolation structures 406 of the periphery region 404 and the spacer 418 along the gate stack 430. The low resistivity layer 428 is also located at a top portion of the periphery doped region 434. Similarly, the low resistivity layer 428 may serve multiple functions but is optional. For example, the low resistivity layer 428 enhances performance of the peripheral circuitry 210.

For illustrative purposes, the stack headers 414 in the core region 402 and the periphery region 404 are depicted as substantially the same, although it is understood that the stack headers 414 may not be the same between the core region 402 and the periphery region 404. Also for illustrative purposes, the low resistivity layer 428 is depicted substantially the same in the core region 402 and the periphery region 404, although it is understood that the low resistivity layer 428 may not be the same between the core region 402 and the periphery region 404.

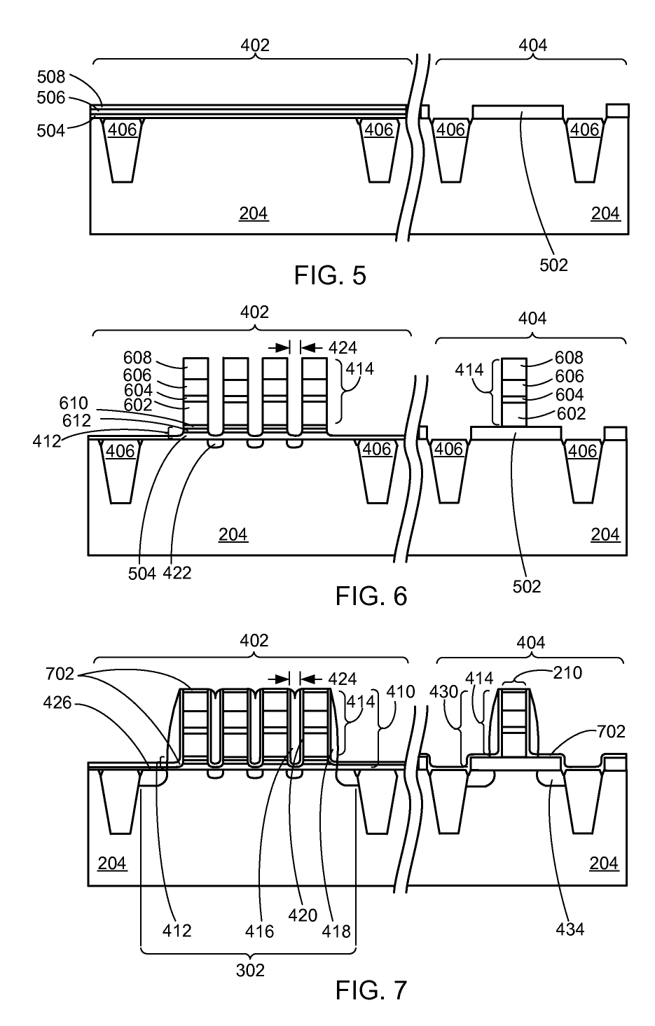

Referring now to FIG. 5, therein is shown a cross-sectional view of the integrated circuit system 200 of FIG. 4 in an isolation phase. The cross-sectional view depicts the core region 402 and the periphery region 404 of the substrate 204. The isolation structures 406 are formed in the substrate 204 both in the core region 402 and the periphery region 404. The isolation structures 406 may be formed by a number of different processes, such as an anisotropic etch at the predetermined locations of the substrate 204 with an insulator fill.

A first insulator layer 504, a charge trap layer 506, and a second insulator layer 508 are preferably formed in the core region 402. The first insulator layer 504, the charge trap layer 506, and the second insulator layer 508 may be formed in a number of ways. For example, layers of the first insulator layer 504, the charge trap layer 506, and the second insulator layer 508 may be formed non-selectively and removed from the periphery region 404 with lithographic and etch techniques.

A dielectric layer 502 is preferably formed selectively in the periphery region 404. The dielectric layer 502 may be formed by a number of ways. For example, the dielectric layer 502 may be grown or deposited and patterned with lithographic and etch techniques.

The charge trap layer 506 may be formed in a number of ways. For example, the charge trap layer 506 may be formed with a silicon-rich nitride layer (SRN or SiRN) or silicon nitride (Si_{X}N_{Y}) film with chemical vapor deposition process (CVD) using NH₃ and SiCl₂H₂ but not limited to the two chemicals. A ratio of the gases, such as NH₃:SiCl₂H₂, range from 1:40 to 1:1 can produce silicon-rich nitride with a ratio of Si to N higher than 0.75. As another example, the charge trap layer 506 may also be formed with atomic layer deposition (ALD).

For illustrative purposes, the charge trap layer 506 is shown as a single layer, although it is understood that the charge trap layer 506 may have multiple layers, such as a nitride layer over a silicon rich nitride layer. Also for illustrative purposes, the charge trap layer 506 is shown as a single uniform layer, although it is understood that the charge trap layer 506 may include one or more layer having a concentration gradient, such as different gradient concentrations of silicon.

The second insulator layer 508, such as an oxide layer or a top blocking layer oxide layer, over the charge trap layer 506 may be formed over the charge trap layer 506 with a number of different processes. For example, the second insulator layer 508 may be formed with thermal oxidation or CVD. As another example, the second insulator layer 508 may also be formed from a top portion of the charge trap layer 506 with slot plane antenna (SPA) oxidation. The first insulator layer 504, the charge trap layer 506, and the second insulator layer 508 collectively will form the charge storage stack 412 of FIG. 4, as will be described later.

Referring now to FIG. 6, therein is shown the structure of FIG. 5 in a stack forming phase. The stack headers 414 are formed in the core region 402 and the periphery region 404. The structure of FIG. 5 has a semi-conducting layer (not shown), such as a polysilicon layer, formed over the core region 402 and the periphery region 404. The semi-conducting layer is over the second insulator layer 508 of FIG. 5, the charge trap layer 506 of FIG. 5, and the first insulator layer 504 of FIG. 5 in the core region 402. The semi-conducting layer is also over the dielectric layer 502 in the periphery region 404. The semi-conducting layer is also over the isolation structures 406 and the substrate 204.

A transition layer (not shown), such as a tungsten nitride (WN) layer, is formed over the semi-conducting layer in both the core region 402 and the periphery region 404. A metal layer (not shown), such as a tungsten (W) layer, is formed over the transition layer in both the core region 402 and the periphery region 404. The transition layer prevents reaction between the metal layer and the semi-conducting layer. A cap layer (not shown), such as a silicon nitride (SiN) layer, is formed over the metal layer.

The layer stack having the semi-conducting layer, the transition layer, the metal layer, and the cap layer undergoes patterning processing, such as a lithographic processing and anisotropic etch, forming the stack headers 414 in the core region 402 and the periphery region 404. Each of the stack headers 414 has a semi-conducting portion 602, such as polysilicon, over the second insulator layer 508, and a transition portion 604, such as tungsten nitride, over the semi-conducting portion 602. Each of the stack headers 414 continues with a metal portion 606, such as tungsten, over the transition portion 604 and a cap portion 608, such as silicon nitride, over the metal portion 606. The metal portion 606 may be connected as the word lines 310 of FIG. 3 of the memory systems 202 of FIG. 2. Adjacent instances of the stack headers 414 in the core region 402 have the gap 424 in between. Similarly, the one instance of the stack headers 414 in the periphery region 404 is concurrently formed.

The formation of the stack headers 414 in the core region 402 does not substantially affect the second insulator layer 508, the charge trap layer 506, the first insulator layer 504, the substrate 204, and the isolation structures 406. The isolation structures 406, the dielectric layer 502, and the substrate 204 in the periphery region 404 are also substantially unaffected by the formation of the stack headers 414.

The periphery region 404 is preferably covered by a mask (not shown), such as a photoresist mask, while the core region 402 is preferably exposed to anisotropic etch which selectively removes exposed areas of the second insulator layer 508 forming a second insulator liner 610 without substantially affecting the charge trap layer 506 and the cap portion 608. The second insulator liner 610 is named as “second” for convenience and consistency with the “second” in the second insulator layer 508 and is not intended to refer to the order of etching.

The anisotropic etch preferably continues to selectively remove the exposed areas of the charge trap layer 506 forming a charge trap liner 612 without substantially affecting the first insulator layer 504 and the cap portion 608. The second insulator liner 610 and the charge trap liner 612 preferably form the charge storage stack 412 that is electrically isolated from one another.

As an example, the second insulator layer 508 and the charge trap layer 506 may not undergo the lithographic process and anisotropic etch described above leaving the second insulator layer 508 and the charge trap layer 506 connected between the stack headers 414 if lateral charge movement in the charge trap layer 506 does not occur within the operating temperature range of the memory systems 202. The mask used for the anisotropic etching described above is removed. The inner doped region 422 formed by preferably exposing the core region 402 to ion implantation while protecting the periphery region 404 with another mask, such as a photoresist mask.

Referring now to FIG. 7, therein is shown the structure of FIG. 6 in a filler forming phase. A dielectric lining 702, such as silicon dioxide, followed by a coating (not shown) of the material of the gap filler 416, such as silicon nitride are preferably formed over the substrate 204 in the core region 402 and the periphery region 404 covering the memory section 302 and the peripheral circuitry 210. The coating fills the gap 424 between adjacent instances of the stack headers 414 and the charge storage stack 412 in the core region 402. The coating undergoes anisotropic etch without substantially affecting the dielectric lining 702 forming the gap filler 416 and the spacer 418. The gap filler 416 is between the adjacent instances of the stack headers 414 and the memory stacks 410. The spacer 418 is along the sidewall 420 of the stack headers 414 and the memory stacks 410 at the ends of the memory section 302 and along the sidewall 420 of the one instance of the stack headers 414 of the gate stack 430.

The structure having the gap filler 416 and the spacer 418 undergo implantation forming the outer doped region 426 and the periphery doped region 434. The implantation process may be performed by a number of different processes, such as ion implantation or multiple implantation steps.

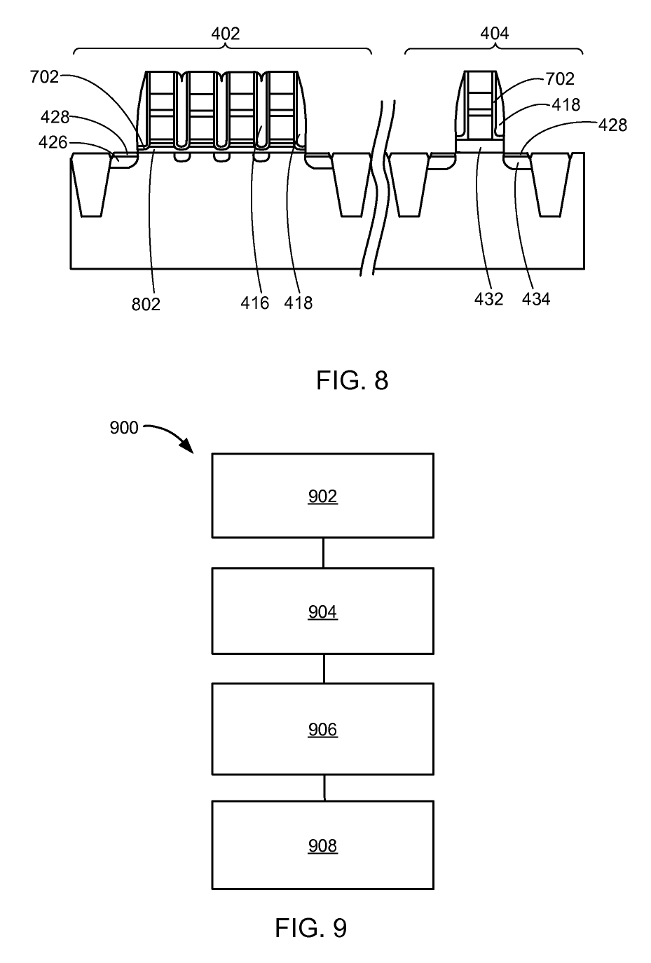

Referring now to FIG. 8, therein is shown the structure of FIG. 7 in a metal forming phase. The structure of FIG. 7 undergoes patterning. Portions of the dielectric lining 702 and the first insulator layer 504 of FIG. 5 exposed by both the gap filler 416 and the spacer 418 in the core region 402 are preferably selectively removed forming a first insulator liner 802 and exposing the outer doped region 426. Similarly, the dielectric lining 702 and the dielectric layer 502 of FIG. 5 exposed by both the gap filler 416 and the spacer 418 in the periphery region 404 are preferably selectively removed forming the dielectric liner 432 and exposing the periphery doped region 434.

A conductive layer (not shown), such as a Ti, Co, Ni, or Pt, is preferably deposited and annealed to allow silicide formation. The conductive layer undergoes sintering, such as rapid thermal process (RTP), diffusing the conductive layer to the surface of the outer doped region 426 and the periphery doped region 434. The unreacted portions of the conductive layer is removed by a number of different process, such as etching, forming the low resistivity layer 428 of the outer doped region 426 and the periphery doped region 434. Further processing, such as forming interconnects, may be performed for forming the integrated circuit system 200.

Referring now to FIG. 9, therein is shown a flow chart of an integrated circuit system 900 for manufacture of the integrated circuit system 200 in an embodiment of the present invention. The system 900 includes forming a substrate having a core region and a periphery region in a block 902; forming a charge storage stack over the substrate in the core region in a block 904; forming a gate stack with a stack header having a metal portion over the substrate in the periphery region in a block 906; and forming a memory system with the stack header over the charge storage stack in a block 908.

These and other valuable aspects of the embodiments consequently further the state of the technology to at least the next level.

Thus, it has been discovered that the integrated circuit system method and apparatus of the present invention furnish important and heretofore unknown and unavailable solutions, capabilities, and functional aspects for integrated systems. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. A method for forming an integrated circuit system comprising:
forming a substrate having a core region and a periphery region;
forming a charge storage stack over the substrate in the core region;
forming a gate stack with a stack header having a metal portion over the substrate in the periphery region; and
forming a memory system with the stack header over the charge storage stack.

2. The method as claimed in claim 1 wherein forming the charge storage stack includes:
forming a first insulator liner over the substrate;
forming a charge trap liner over the first insulator liner; and
forming a second insulator liner over the charge trap liner.

3. The method as claimed in claim 1 further comprising forming the stack header includes:
forming a semi-conducting portion over the substrate;
forming a transition portion over the semi-conducting portion; and
forming the metal portion over the transition portion.

4. The method as claimed in claim 1 further comprising forming memory cells with an inner doped region in the substrate under a gap between memory stacks of the memory system.

5. The method as claimed in claim 1 further comprising forming an electronic system or a subsystem with the integrated circuit system.

6. A method for forming an integrated circuit system comprising:
forming a substrate having a core region and a periphery region;
forming a charge storage stack over the substrate in the core region;
forming a dielectric liner over the substrate in the periphery region;
forming a gate stack with a stack header having tungsten portion over the dielectric liner; and
forming a memory system with the stack header over the charge storage stack.

7. The method as claimed in claim 6 further comprising forming the stack header includes:
forming a semi-conducting portion over the substrate;
forming a transition portion having nitride over the semi-conducting portion; and
forming the tungsten portion over the transition portion.

8. The method as claimed in claim 6 further comprising:
forming an outer doped region in the core region;
forming a periphery doped region in the periphery region; and
forming a low resistivity layer on the outer doped region and the periphery doped region.

9. The method as claimed in claim 6 further comprising forming a periphery doped region in the substrate in the periphery region not under the gate stack.

10. The method as claimed in claim 6 wherein forming the substrate having the core region and the periphery region includes forming an isolation structure in the substrate between the core region and the periphery region.

11. An integrated circuit system comprising:
a substrate having a core region and a periphery region;
a charge storage stack over the substrate in the core region;
a gate stack having a stack header having a metal portion over the substrate in the periphery region; and
a memory system having the stack header over the charge storage stack.

12. The system as claimed in claim 11 wherein the charge storage stack includes:
a first insulator liner over the substrate;
a charge trap liner over the first insulator liner; and
a second insulator liner over the charge trap liner.

13. The system as claimed in claim 11 wherein the stack header includes:
a semi-conducting portion over the substrate;
a transition portion over the semi-conducting portion; and
the metal portion over the transition portion.

14. The system as claimed in claim 11 further comprising memory cells having an inner doped region in the substrate under a gap between memory stacks of the memory system.

15. The system as claimed in claim 11 further comprising an electronic system or a subsystem with the integrated circuit system.

16. The system as claimed in claim 11 wherein:
the substrate is a semiconductor substrate having the core region and the periphery region;
the charge storage stack has silicon rich nitride over the substrate in the core region;
the gate stack has the stack header over a dielectric liner, the dielectric liner is over the substrate in the periphery region; and
the memory system, having the stack header over the charge storage stack, has a memory stack having the stack header.

17. The system as claimed in claim 16 wherein the stack header includes:
a semi-conducting portion over the substrate;
a transition portion having nitride over the semi-conducting portion; and
the tungsten portion over the transition portion.

18. The system as claimed in claim 16 further comprising:
an outer doped region in the core region;
a periphery doped region in the periphery region; and
a low resistivity layer on the outer doped region and the periphery doped region.

19. The system as claimed in claim 16 further comprising a periphery doped region in the substrate in the periphery region not under the gate stack.

20. The system as claimed in claim 16 further comprising an isolation structure in the substrate between the core region and the periphery region.
